(19) United States
(12) Patent Application Publication
(10) Pub. No.: US 2015/0274924 A1
(43) Pub. Date: Oct. 1, 2015

(54) ELECTROSTATIC DISSIPATIVE FOAMS AND PROCESS FOR THE PREPARATION THEREOF

(71) Applicant: Council of Scientific & Industrial Research, New Delhi (IN)

(72) Inventors: Jai Krishna PANDEY, Dhanbad (IN); Shrenik Madhusudan TRIVEDI, Ahmedabad (IN); Rushay Shrenik TRIVEDI, Ahmedabad (IN); Urja Falgun JANI, Ahmedabad (IN); Bhavtosh Rajnikant VYAS, Ahmedabad (IN); Ajay KUMAR, Ahmedabad (IN)

(21) Appl. No.: 14/676,328

(22) Filed: Apr. 1, 2015

(30) Foreign Application Priority Data
Apr. 1, 2014 (IN) 0944/DEL/2014

(51) Int. Cl. C08J 9/36; H05K 9/00; B05D 1/18

(52) U.S. Cl. CPC C08J 9/365; B05D 1/18; H05K 9/0079; C08J 2375/04; C08J 2300/00; C08J 2397/02; C08J 2201/036; C08J 2201/038; C08J 2479/02

(57) ABSTRACT

The present invention relates to the development of electrostatic dissipative (ESD) electronic packaging materials based on the electrically conducting nanofiller decorated polyurethane foams and also describes a process for the preparation of the same. More specifically it relates to the development of electrically conducting foams by providing a coating of 0.003 to 2.97 vol % loading of electrically conducting materials (like conducting polymers, functionalized carbon nanotubes, graphene analogues etc) over/onto otherwise electrically insulating surface of foams. The combination of low density, mechanical flexibility, resilience and surface conductivity collectively contribute towards their excellent shock absorption and static charge dissipation capabilities. In particular, these foams display surface resistivity value <10⁹ ohm/sq and static charge dissipation time <0.5 sec, which clearly demonstrate their potential for electronic packaging applications. Besides, these foams could also be useful for antistatic dust filters, clean-room/medical apparels, static-free footwear, static dissipative upholstery items, antistatic/dissipative floorings/tiles etc.

### CROSS-REFERENCE TO RELATED APPLICATIONS

This application claims priority to Indian Application No. 0944/DEL/2014, filed Apr. 1, 2014, the disclosure of which is incorporated herein by reference in its entirety.

### FIELD OF THE INVENTION

Present invention relates to electrically conducting nanofillers (ECNFs) decorated conducting foams. Particularly, present invention relates to process for the preparation of the electrostatic dissipative foams. More particularly, present invention relates to electrostatic dissipative foams for prevention of contact electrification as well as safe dissipation of any surface charge generated due to triboelectric charging.

### BACKGROUND OF THE INVENTION

Many materials, especially polymers (e.g. plastics/rubbers) easily become electrostatically charged when rubbed against other materials. Such triboelectric charging can be used constructively e.g. in photocopying, electrostatic clamping and the retention of powder in electrostatic precipitation and paint spraying. In contrast, the tribogenerated electrostatic charge and related potential are risky and can cause problems in many areas of industry. Particularly, the uncontrolled electrostatic dissipation (ESD) can cause ignition of flammable gases and give electrical shocks to personnel working on shop floors. Antistatic agents are always added in jet fuels to avoid fire hazards in fuel pumps and airline fuel delivery systems. The static charges can make thin films and light fabrics cling, attract airborne dust and debris, damage semiconductor devices and upset the operation of microelectronic equipment. Further, considering the fact that, these days; electronic devices are being widely used in the industries, offices and homes, the uncontrolled electrostatic phenomena may cause damage to electronic devices or it may also pose serious threat to human safety/health. The cost of damage of electronic components/devices by ESD is estimated to be of the order of billions of dollars per annum. ESD protection can be done by two ways viz: (i) by elimination of tribogenerated static charges by effectively conducting them to ground and (ii) by prevention of the generation of static charges in the first place. Static charges are generated by the triboelectric effect, simply by rubbing or separating surfaces which causes the transfer of electrons. This triboelectric generation is common with insulating packaging/encasing materials like plastics or glasses. To overcome this effect, antistatic/electrostatic dissipative materials needs to be developed for ultimate applications in ESD safe floorings (titles/mats), instrument housings (cabinets/shelves), apparels (aprons, masks, bodysuits), footwear (shoes, sleepers, socks), furniture/upholstery (seats, benches, cushions, covers, belts/straps), miscellaneous items (mobile phone pouches, hand tools, wristbands) and electronic packaging/encasing materials. The conventional antistatic or static dissipative materials available in the market are either metal based (e.g. surface coating of metals, metallic stripe or wire included within a non-conductive bulk material) or filled composites (e.g. polymeric matrices consisting of conducting network of fillers like graphite, carbon black, carbon fibers, carbon nanotubes or graphene; conducting polymers; metallic particles/fibers/whiskers etc.), with associated issues that make them commercially unviable as electronic packaging material. In the present work, we have developed the promising ESD safe packaging material based on composite foams, by coating functionalized carbon nanotubes, graphene and conducting polymers with different loadings on insulating polyurethane (PU) foam. The foams used have characteristic properties such as low density, mechanical flexibility, corrosion resistance and sufficient electrical conductivity to reduce the generation of triboelectric charges or to ensure rapid & safe disposal of any surface static charge.

The explosive growth of electronics and miniaturization of devices has produced electrostatic charging (ESC) and related electrostatic discharge (ESD) as most undesirable byproduct. ESC is a critical issue especially during the handling of sensitive electronic items (e.g. data storage devices, IC chips, medical instruments etc.) due to their susceptibility towards electrostatic discharge (ESD). Dust attraction by statically charged articles and television screen picture edge distortion/discoloration represent another frequently encountered consequence of ESC. The uncontrolled ESD during transportation of hazardous chemicals may lead to explosion or fire hazards with serious threat to environment or even precious human life. Therefore, suitable counter-measures must be taken to restrict or eliminate the harmful effects of static electricity. In principle, the electrical conduction is the most important requirement for designing anti-ESC and static dissipative materials which should satisfy the antistatic criteria of surface resistivity <10¹² ohm/sq and 10% static charge dissipation time <2.0 sec. Metal based coatings or filled composites are by far the most widely used materials for ESD; however, metals possess high density, corrosion susceptibility and processing difficulties. Similarly, carbonaceous filled compositions have disadvantages in terms of poor dispersion and agglomeration of nanofillers. In this work, we have synthesized static dissipative foams by providing a coating of electrically conducting materials (like conducting polymers, functionalized carbon nanotubes, graphene analogues etc) over/onto otherwise electrically insulating surface of foams. These foams possess low density, mechanical flexibility, corrosion resistance and sufficient electrical conductivity to drain static charges. Particularly, their surface resistivity value <10⁹ ohm/sq and static charge dissipation time <0.5 sec, demonstrate their excellent static charge dissipation capability and suggest their suitability for ESC/ESD free electronic packaging applications. The most other works speculate the use of graphene based composites for ESD applications solely on the basis of electrical conductivity; we presented first quantitative measurement of antistatic decay time.

The worldwide problem of ESD including malfunctioning of electronic items, fire hazards and financial/human-life loss, justify the need of IPR protection of such multifunctional composites which may also be useful for antistatic dust filters, clean-room/medical apparels, footwear, static dissipative upholstery items etc.

The electrically conducting foams comprising of a coating of electrically conducting materials over/onto otherwise electrically insulating surface of foams, represent a class of multifunctional materials that display unique combination of properties like surface conductivity, flexibility, resilience, low density, hydrophobicity, sound/vibration damping characteristics and improved environmental weathering resistance. These attributes collectively contribute towards their excellent shock absorption and static charge dissipation capabilities making them ideal candidate for electronic packaging applications. The simple solution based route for providing the adherent coating of variety of electrically conducting fillers such as conducting polymers, functionalized carbon nanotubes, graphene analogues etc., over insulating substrate like foam, fabrics, provides an added advantage in terms of simplicity, economics and scalability of the process. The worldwide problem of ESD including malfunctioning of electronic items, fire hazards and financial/human-life loss, justify the need of IPR protection of such multifunctional composites which may also be useful for antistatic dust filters, clean-room/medical apparels, footwear, static dissipative upholstery items etc. There are several patents and papers on the conducting foam based antistatic and static dissipative materials.

Patent EP2410004A1 [Gkn Aerospace Transparency System, Inc Garden Grove Calif. 92841 (US), Transparent Polyurethane Protective Coating, Film and Laminate Compositions with Enhanced Electrostatic Dissipation Capability, and Methods for Making Same, EP2410004A1, 2012] deals with the development of transparent polyurethane laminate or multi-layer coating comprising a first transparent polyurethane layer, a middle conductive material layer (made up of nanostructured metal oxide e.g. ITO) disposed on the first transparent polyurethane layer, and a second transparent polyurethane layer disposed on the conductive layer. These laminates reduces the problem of static charge buildup on aircraft transparencies by allowing charge to drain through the second transparent polyurethane layer to the conductive material layer and then to the edge of the conductive material layer, where it is mated to the airframe. However, metal oxides coatings are brittle, susceptible to corrosion and known to have poor weathering properties e.g. poor cracks/wear resistance. The nanoparticle dispersion may be cured with a silicate binder. The volume resistivity value was >10¹¹ ohm-cm and actual static decay time was not mentioned.

US patent US 20110147675A1 [J. Krause, B. Breuer, M. Heinemann, R. Jumel, Antistatic or electronically conductive polyurethanes, and method for the production thereof, US patent 2011, 20110147675] relates to an antistatic or electrically conductive, thermoset polyurethane obtained by reacting A) an organic polyisocyanate; B) a compound comprising NCO-reactive groups; and C) optionally a catalyst, a blowing agent, an auxiliary, an additive, or mixtures thereof; and wherein, the polyurethane comprises a carbon nanotube present in an amount of from 0.1 to 15% by weight based on the total weight of the polyurethane. However, the surface resistivity or static charge decay time was not mentioned.

References may be made to U.S. Pat. No. 4,301,040, which describes a process for preparation of a static-free, polymeric surface mat to prevent the accumulation of static charge, particularly in the pack aging and handling of electronic components and devices, which mat comprises a nonconductive, synthetic material layer with a top surface, optionally an adhesive layer on the bottom surface of the synthetic material, and a solid or foam layer of a conductive material, such as an open-cell urethane foam impregnated with 2-40 weight % of finely divided conductive particles (finely-divided metal particles, such as silver, aluminum and metal salts, such as aluminum silicate, graphite, other carbon foams, preferably carbon-black particles or combination of them) and a film-forming binder material to secure the particles uniformly onto the foam. However, these mats display surface resistance characterized by surface resistance of the coated conducting foam (<5,000 ohms per square inch) whereby static charges, accumulating on the top surface of the synthetic sheet material, are dissipated through the electrically conductive layer. The actual static decay time was not mentioned.

References may be made to Journal by Saini et al. entitled “Enhanced electromagnetic interference shielding effectiveness of polyaniline functionalized carbon nanotubes filled polystyrene composites”, J. Nanoparticle Resea. 15, 2013, 1-7] have synthesized Multiwall carbon nanotubes (MWCNTs)/polystyrene composites by solution processing route using non-covalently functionalized (polyaniline coated) MWCNTs. These composites exhibit an extremely low percolation threshold (0.12 vol. % MWCNT) and found to have potential applications in the areas of electromagnetic interference (EMI) shielding and electrostatic dissipation (ESD) with an ESD time of 0.78 s (for 0.5 vol. % MWCNT) and shielding effectiveness of −23.3 dB (>99% attenuation). However, these composites were not flexible and belong to category of non-cellular materials with relatively higher density (>0.8 g/cm³) than lightweight foamed materials.

Hodlur et al. [R. M. Hodlur and M. K. Rabinal, Graphene based Polyurethane Material: As Highly Pressure Sensitive Composite, AIP Conf. Proc. 1447, 2012, 1279-1280] have prepared graphite oxide (GO) coated flexible polyurethane foams that were made electrically conducting by converting insulating GO to conducting graphene by chemical reduction. The foam with 3 weight % loading of graphene provides electrical conductivity to the foams. However, these foams were demonstrated for pressure sensing applications and actual surface resistivity values were not mentioned. The highly uncompressed samples show resistance value of 10⁹-10¹⁰Ω, which is very high compared 3 wt % loading of reduced graphene oxide (RGO) (which can give similar resistance below 0.5 wt % loading) and gives indication of absence of exfoliation of formed GO. Further, such high resistance may be useful for antisatic application but not conform to static dissipative criteria.

Saini et al. [P. Saini, V. Choudhary, S. K. Dhawan, Improved microwave absorption and electrostatic charge dissipation efficiencies of conducting polymer grafted fabrics prepared via in situ polymerization. Polym. Adv. Technol., 23 (2012) 343-349] have prepared polyaniline (PANT) and polypyrrole (PPY) were grafted over cotton fabrics by in situ polymerization. The fabrics display electrical conductivity of 10⁻³ to 10⁻⁴ S/cm with fast dissipation of static charge (decay time <0.01 sec). However, the involved polymerization process also leads to nodular growth, wastage of conducting polymer and involvement of costly chemicals that makes the commercialization bit difficult. Further, the strong acidic conditions involved during polymerization may adversely affect the mechanical strength of some types of fabrics.

H. L. Frisch J. M A, H. Song, K. C. Frisch, P. C. Mengnjoh, A. H. Molla, Hybrid Electrically Conductive Polyaniline/Polyurethane Foams, J. Appl. Polym. Sci. 80 (2001) 893-897] have synthesized electrically conductive rigid- and flexible-polyaniline/polyurethane foams by in-situ polymerization of aniline monomer containing immersed PU foam and Hydrochloric acid (HCl). The pH dependence of the properties was shown and the DC conductivity of the flexible foam prepared at pH 0.505 was found to be about ˜0.05 S/cm. Further, PANI loading was relatively high (29.67 wt % to 85.1 wt %) and coating tends to shed. Similarly, for rigid foam, PANI loading was exceptionally high and varies from 92.3 wt % (for foam with conductivity of) to 93.8 wt % (for foam with conductivity of). Such large amount of PANI tends to sheds from the foam's surface leading to deterioration of conductivity with time. Further, the dopant HCl has tendency to escape from the polymer, which not only cause undoping of coated polymer (resulting in conductivity deterioration with time) but may also adversely affect (due to extremely corrosive nature of HCl gas/vapours) the sensitive electronic components containing metallic encasing, sub-components or electronic circuitry. Therefore, such composites cannot be used as static dissipative packing/encasing materials for metallic components or sensitive electronic items.

Muthukumar et al. [Muthukumar N. and Thilagavathi G., Design and development of conducting polyurethane foam sensors for breathing frequency measurement, Int. J. Textile Fashion Technol., 1, (2011) 21-31] fabricated PANI coated PU foam by in-situ polymerization of aniline in the presence of hydrochloric acid (HCl). The resistance of the PANI coated foam was ˜7×10³ ohm and the PANI loading level was not mentioned. Due to pressure dependent conductivity, this foam was used for making a breathing monitor, whereby the foam sensor is incorporated into an elastic belt to wrap around the ribcage area. This sensor utilizes change in conductivity with pressure to monitor breathing. Nevertheless, due to corrosive nature of dopant HCl, the may not be useful for static dissipative or antistatic applications and related static charge free packagings.

### OBJECTIVES OF THE INVENTION

Main objective of the present invention is to provide electrically conducting nanofillers (ECNFs) decorated conducting foams.

Another object of the present invention is to provide electrically conducting nanofillers (ECNFs) (e.g. nanostructured conducting polymers, functionalized carbon nanotubes, graphene analogues) decorated foams, for prevention of contact electrification as well as safe dissipation of any surface charge generated due to triboelectric charging.

Yet another objective of the present invention is to provide a process for the development of electrically conducting nanofillers (ECNFs) decorated foams.

Yet another objective of the invention is to provide the electrical conductivity to the foamed substrates by attachment of different ECNFs on the otherwise electrically insulating surfaces of the foams.

Yet another objective of the invention is to preserve the porous structure of the foam even after decoration with different ECNFs.

Yet another objective of the invention is to control the electrical properties by varying the nature of conducting coating (i.e. conducting polymer or carbon based) as well as loading level of material between 0.003 to 2.97 volume %.

Yet another objective of the invention is to regulate the surface resistivity between value 10⁴ to 10¹¹ ohm/sq and maintaining static decay time <2.0 second by controlling the nature and loading level of ECNFs.

Yet another objective of the invention is to control the density of foam between 0.0159 to 0.0515 g/cm³ (i.e. to assure lightweight) and porosity between 95.1-98.5% (i.e. to preserve foamed structure) with maintenance of flexibility, introduction of hyphobicity and good resilience that provides physical cushioning by absorbing mechanical shocks/vibrations.

Yet another objective of the present invention is to provide a process for the development of lightweight (density in the range 0.0159 to 0.0515 g/cm³), flexible (can be easily bent, rolled or folded), hydrophobic (contact angle >90°), corrosion resistant (unlike metals which tend to corrode) antistatic and static dissipative (surface resistivity in the range 10¹¹ to 10⁴ ohm/sq and static decay time <2.0 seconds) foams (porosity in the range 95.1-98.5%), comprising of 0.003 to 2.97 volume % ECNF decorated porous/foamed substrate, wherein the conducting coating with both electrical conductivity and good adherence to substrate is fabricated by improved process (wet-chemical route involving transfer of ECNFs from dispersed phase to the porous substrate followed by drying and post treatment) thus enabling onset of surface conduction with preservation of physical and mechanical properties of foamed substrate.

Yet another objective of the invention is to develop electrically conducting foams with antistatic and static dissipative characteristics for, (a) prevention of contact electrification as well as safe dissipation of any surface charge generated due to triboelectric charging making it suitable for ESC/ESD free electronic packaging applications, (b) possible making of static charge free apparels (clean room or medical garments), footwears or upholstery and (c) possible use in antistatic dust filters or static free floor mats or wall claddings.

### BRIEF DESCRIPTION OF THE DRAWINGS

FIG. 1: Optical images of (a) blank foam, (b) RGO decorated foam, (c) PANI-DBSA decorated foam and (d) f-CNT decorated foam.

FIG. 2: SEM image of PANI-DBSA decorated foam. Inset shows the enlarged view of the surface of the foam having agglomerated polyaniline-DBSA nanorods present over the surface of foam.

FIG. 3: SEM image of f-CNT decorated foam. Inset shows the enlarged view of the surface of the foam revealing the presence of electrically conducting network of f-CNTs present over the surface of foam.

FIG. 4: SEM image of RGO decorated foam. Inset shows the overlapping graphene sheets present over the surface of foam providing it electrical conductivity.

FIG. 5: Surface resistivity measurement for blank foam (left image, resistivity-10¹² Ω/Sq) and graphene decorated foam (right image, resistivity ˜10⁷ Ω/Sq).

FIG. 6: Static charge decay profiles of blank foam and RGO coated foam. Inset shows the rapid charge dissipation characteristics of RGO based foam.

### SUMMARY OF THE INVENTION

Accordingly, present invention provides electrically conducting nanofillers (ECNFs) decorated conducting foams comprising of decoration of 0.003 to 2.97 volume % of ECNFs over otherwise electrically insulating surface of foam providing them electrical conductivity without disturbing foamed morphology, physical or mechanical properties.

In an embodiment of the present invention, electrically conducting nanofillers (ECNFs) used are selected from the group consisting of activated carbon, exfoliated graphite, carbon based filler or doped conducting polymers wherein the dopant is selected from a group comprising of para toluene sulfonic acid (PTSA), cardanol azophenyl sulfonic acid (CDSA) and dodecyl benzene sulfonic acid (DBSA), camphor sulfonic acid (CSA), Lignin sulfonic acid (LSA) preferably DBSA.

In another embodiment of the present invention, conducting polymer is selected from the group consisting of polyaniline, polypyrrole or polythiophenes preferably polyaniline.

In yet another embodiment of the present invention, the carbon based filler is selected from a group comprising of graphene, graphene oxide (GO), functionalized carbon nanotubes (f-CNTs) or activated carbon fibers.

In yet another embodiment of the present invention, said foam exhibit density in the range of 0.0159 to 0.0515 g/cm³, porosity is in the range of 95.1 to 98.5%, surface resistivity is in the range of 10¹¹ to 10⁴ ohms/square and static charge decay time of <2.0 seconds.

In yet another embodiment of the present invention, said foam is useful for electronic packaging applications, antistatic dust filters, clean-room/medical apparels, footwear and static dissipative upholstery items.

In yet another embodiment, present invention provides a process for the preparation of ECNFs decorated conducting foams comprising the steps of:
(i) addition of ECNFs in dispersion medium to obtain a 0.001-0.5% (w/v) dispersion;
(ii) dipping of the porous substrate inside the dispersion as obtained in step (i) for period in the range of 1 to 5 minutes under agitation to obtain wet impregnated foam;
(iii) drying the wet impregnated foam as obtained in step (ii) at temperature in the range of 40 to 80° C. for period in the range of 4 to 8 h to obtain the ECNFs decorated conducting foams.

In yet another embodiment of the present invention, the porous substrate is selected from the group consisting of polyurethane (PU) foam, fabrics, wood and paper and other porous materials preferably PU foam.

In yet another embodiment of the present invention, the dispersing medium is selected from a group comprising of toluene, benzene, acetone, chloroform, kerosene, distilled water, ethanol, propanol, methanol, dimethylsulfoxide (DMSO), dimethylformamide (DMF), N-methyl pyrrolidone (NMP), either alone or combination thereof.

In yet another embodiment of the present invention, the dispersion medium is preferably chloroform for PANI nanorods and preferably distilled water for both f-CNTs and GO.

In yet another embodiment of the present invention, they also display mechanical flexibility (can be bent, rolled or wrapped), resilience (shock absorbing ability), good corrosion resistance, sound/vibration damping characteristics and static charge dissipation capabilities to act as an ideal candidate for electronic packaging applications.

### DETAILED DESCRIPTION OF THE INVENTION

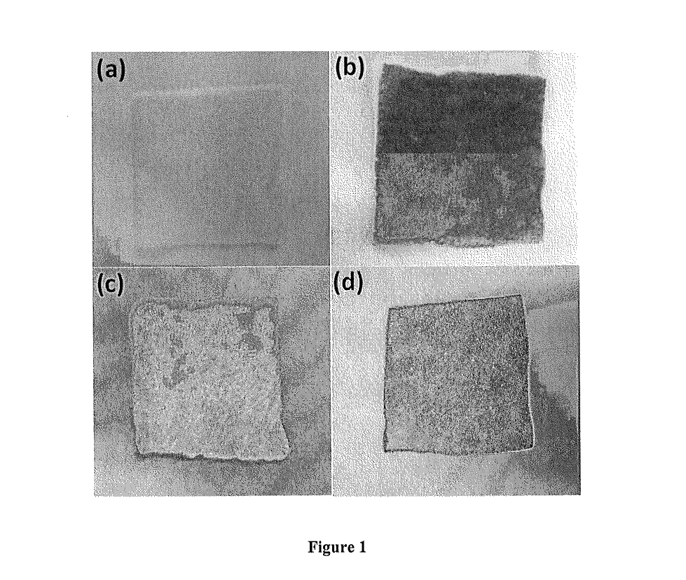

Present invention provides lightweight, mechanically flexible, resilient, antistatic and electrostatic dissipative foams by decoration of 0.003 to 2.97 volume % of ECNFs (graphene, carbon nanotubes or conducting polymer) over otherwise electrically insulating surface of foam providing them electrical conductivity without disturbing foamed morphology or physical/mechanical properties. These foams display unique combination of properties like low surface resistivity density (10″ to 10⁴ ohms/square), low density (0.0159 to 0.0515 g/cm³), high porosity (95.1 to 98.5%) and static charge decay time of <2.0 seconds. In addition, they also display mechanical flexibility (can be bent, rolled or wrapped), resilience (shock absorbing ability), good corrosion resistance, sound/vibration damping characteristics, hydrophobicity and improved environmental weathering resistance. The above attributes collectively contribute towards their excellent shock absorption and static charge dissipation capabilities making them an ideal candidate for electronic packaging applications. The simple solution based route for providing the adherent coating of variety of electrically conducting fillers such as conducting polymers, functionalized carbon nanotubes, graphene analogues etc., over insulating substrate like foam (FIG. 1) or fabrics, represent a simple, economically feasible and scalable process compared to other coating methods like:
(i) Vacuum evaporation of metals (involves high temperature, complex process, time consuming, difficult to achieve uniform coating, high material wastage, corrosion susceptibility of coatings).
(ii) Electroless deposition of metals (complex process requiring sensitizer, initiator and costly solvents, environmental concerns due to toxic chemicals, leads to material wastage).
(iii) In-situ polymerization of conducting polymers (provides no control over loading level, may affect foam's properties, involves costly chemicals, material wastage due to bulk polymerization).
(iv) Coating of unfunctionalized CNTs dispersions (leads to non-uniform and non-adherent coating with poor control over loading level).
(v) Coating of functionalized graphenes (complex process, high cost, moderate adherence and comparatively higher loadings required compared to graphene oxide precursor route).

In addition, the surface decoration route do not affect the properties of the foamed substrate whereas the filled composite route (which involve dispersion of electrically filler inside insulating host polymeric matrix) always (even near percolation) leads to disturbance of physical/mechanical properties of the matrix polymer due to dispersion difficulty and agglomeration issues associated with the nanofillers. Further, it's difficult to control the electrical and physico-mechanical properties of filled nanocomposite foams. Besides, the formation of filled nanocomposites via solution or melt blending route is costly, bit complex and suffered from the dispersion/agglomeration issues of the nanofillers.

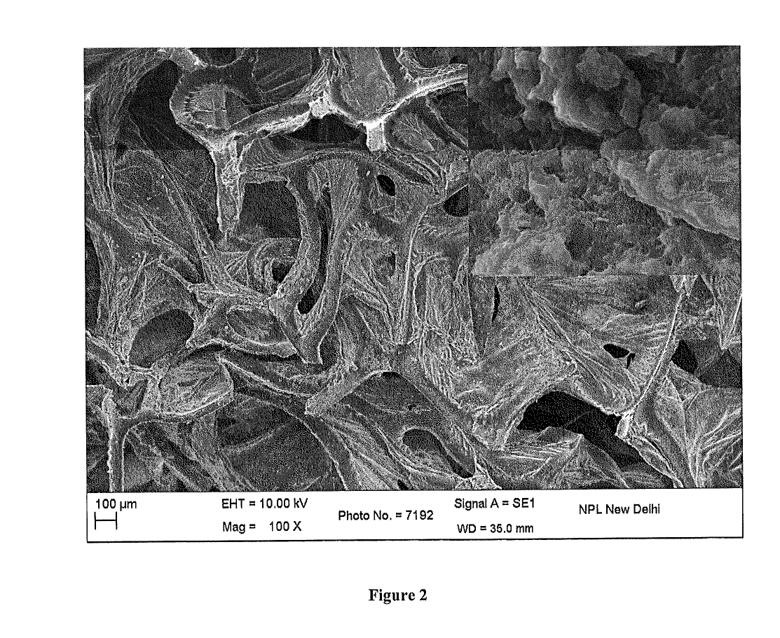

Conducting foam with antistatic and static charge dissipation characteristics comprised of conducting polymer polyaniline (PANT) nanorods decorated foamed substrate prepared by a method (Method 1) involves the following steps. Dispersion of suitable surfactants dopant [para toluene sulfonic acid (PTSA), cardanol azophenyl sulfonic acid (CDSA) and dodecyl benzene sulfonic acid (DBSA), Naphthalene sulfonic acid (NSA), camphor sulfonic acid (CSA), Lignin sulfonic acid (LSA), preferably DBSA) in water using high speed homogenization (blending at >10000 rpm) for specified time (10-60 minutes) to form aqueous emulsion of known concentration (preferably 0.3 M DBSA) followed by addition of monomer (aniline, pyrrole and thiophene, preferably aniline) under continued homogenization for specified time (10-60 minutes) followed by transfer of mixture to a glass reactor, cooled to −5° C. and initiation of polymerization by drop wise addition of known concentration (preferably 0.1 M) of oxidant [ammonium peroxydisulfate (APS), potassium peroxydisulfate, ferric chloride, preferably APS] solution under continuous agitation. After completion of polymerization (6-8 h), the dark green colored dispersion of polymer (preferably PANT) nanorods was demulsified using solvents (ethanol, iso-propanol, n-propanol, preferably 2-propanol) and filtered followed by dispersion in chloroform under high speed (10000 rpm) homogenization for 30 minutes to form dispersion having 50% solid content. In next step, a known amount of chloroform dispersion of PANI nanorods was diluted with chloroform to form dispersion of 0.002-0.6% (w/v) solid content to which the a piece of foamed substrate of known dimensions (3.5″×3.5″) was added to impregnate with the PANI nanorods to form coating over substrate (FIG. 2) followed by drying at 50-60° C. for 4 h so that the volume % loading of the PANI nanorods was in the range 0.009 to 2.97. These foams display flexibility, density in the range of 0.0159 to 0.0515 g/cm³, porosity in the range of 95.1 to 98.5% and surface resistivity in the range of 10⁹ Ω/square to 10⁴ Ω/square.

Dodecyl benzene sulfonic acid (DBSA) doped polyaniline nanorods is used as conducting polymer coating formed by low temperature chemical oxidative polymerization of aniline monomer via emulsion route.

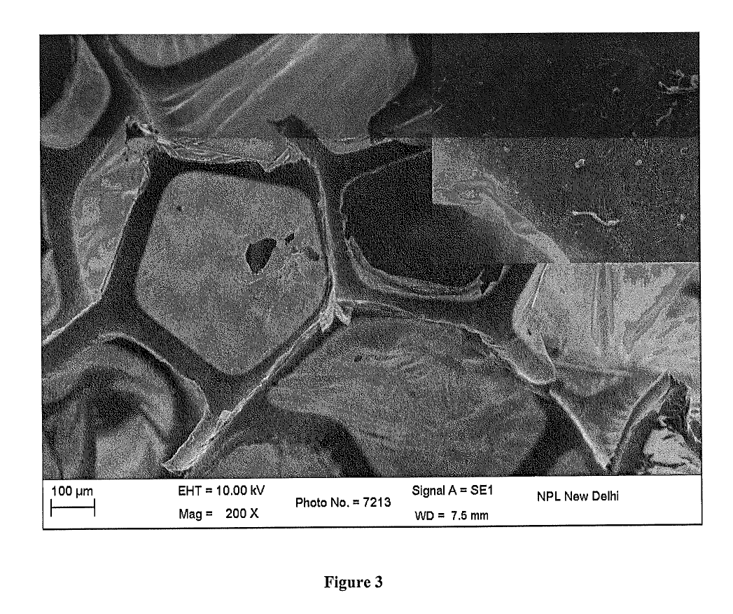

Conducting foam with antistatic and static charge dissipation characteristics comprised of functionalized carbon nanotubes (f-CNTs) decorated foamed substrate prepared by a method (Method 2) involves the following steps. Dispersion of known amount of f-CNTs in distilled water via high speed (10000 rpm) homogenization to from aqueous dispersion with 0.002-0.03% (w/v) solid content to which the a piece of foamed substrate of known dimensions (3.5″×3.5″) was added to impregnate the f-CNTs to form coating of CNT networks over substrate (FIG. 3) followed by oven drying at 50-60° C. for 4 h so that the volume % loading of the f-CNTs was in the range 0.004 to 0.032. These foams display flexibility, density in the range of 0.0159 to 0.0165 g/cm³, porosity in the range of 98.4 to 98.5% and surface resistivity in the range of 10¹⁰ Ω/square to 10⁷ Ω/square.

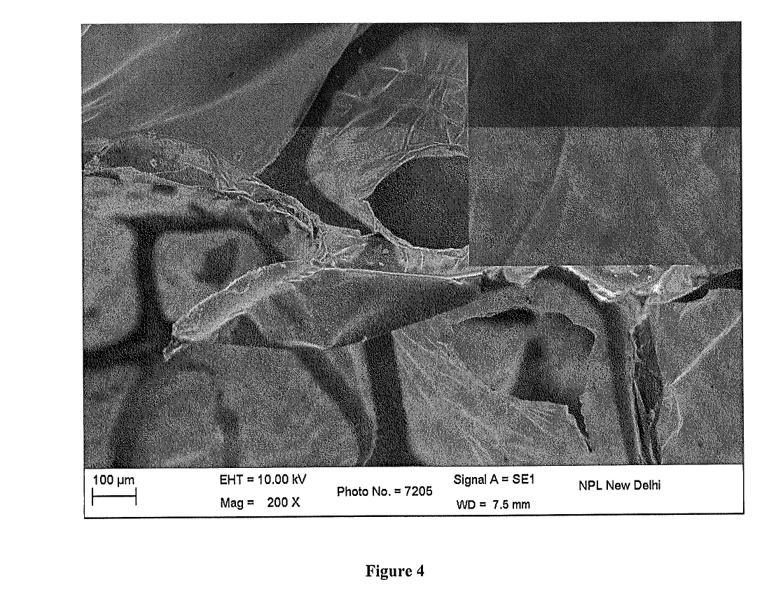

Conducting foam with antistatic and static charge dissipation characteristics comprised of reduced graphene oxide (RGO) decorated foamed substrate prepared by a method (Method 3) involves the following steps. Preparation of GO by hummers method using graphite as source and KMnO₄/NaNO₃ as oxidant. This is followed by dispersion of known amount of synthesized GO in distilled water with 0.02-0.3% (w/v) solid content to which the a piece of foamed substrate of known dimensions (3.5″×3.5″) was added to impregnate the GO to form coating over substrate followed by oven drying at 50-60° C. for 4 h and subsequent reduction by exposure to hydrazine vapours for 12 h to convert GO in RGO so that the volume % loading of the RGO sheets over foamed substrate (FIG. 4) was in the range 0.003 to 0.254. These foams display flexibility, density in the range of 0.0160 to 0.0295 g/cm³, porosity in the range of 97.2 to 98.5% and surface resistivity in the range of 10¹⁰ Ω/square to 10⁴ Ω/square.

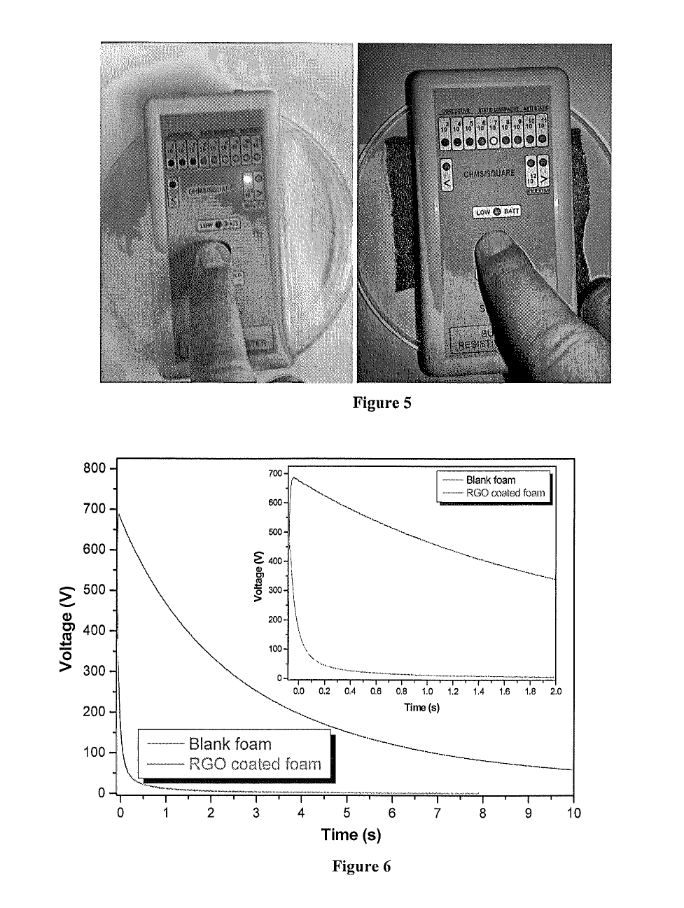

The ECNFs decorated electrically conducting foam is tested for electrostatic compliance by measuring the surface resistivity of the samples via two probe technique using a surface resistivity meter. The meter gives visual indication by distinct glow of LED corresponding to given resistivity value in ohms per square. When a blank (uncoated) control sample of foam was place the Red LED glows (FIG. 5, left image) corresponding to surface resistivity of 10¹² Ω/square. However, when ECNFs coated sample was used LED corresponding to lower resistivity value glows e.g. Orange LED (FIG. 5, right image) corresponding to surface resistivity of 10⁷ Ω/square glows for RGO based foam with RGO loading of 0.024 volume %. According to the LED glow and on observed resistivity value proper compliance (insulating, antistatic, static dissipative or conductive) may be assigned to the samples.

The measurement of actual static decay time was done by applying a corona charging voltage of ±5.0 kV and recording the voltage till it decayed to 10% of the accepted surface voltage (i.e. 10% cut-off limit). The results are presented in form of voltage versus time plots showing voltage decay profiles as shown in FIG. 6 for blank foam (which failed to dissipate the charge) and 0.024 volume % RGO decorated foam (which rapidly dissipate the accepted surface charge within 0.2 seconds).

### EXAMPLES

The following examples are given by way of illustration and therefore should not be construed to limit the scope of the present invention.

### Example 1 to 5

### Preparation of Polyaniline Coated Foam

Polyaniline (PANT) decorated foam is prepared by wet chemical route using chloroform dispersion of PANI nanorods to impregnate foamed substrate followed by evaporation of chloroform leaving behind electrically conducting network of PANI nanorods over foam's surface. PANI nanorods are prepared by low temperature (−5° C.) chemical oxidative polymerization (via emulsion route) of aniline (AN) monomer in the presence of surfactant dopant i.e. dodecyl benzene sulfonic acid (DBSA).

In a typical reaction, aqueous emulsion of 0.3 M DBSA is prepared by high speed homogenization (via MICRA, D8 rotating at >10000 rpm) for 30 min, followed by addition of 0.1 mol AN (aniline) and homogenization is continued for another 30 min. Thereafter, the reaction mixture is transferred to a glass reactor, cooled to (−) 5° C. under continuous stirring and is subsequently polymerized by dropwise addition of 150 ml aqueous solution of 0.1 mol ammonium peroxydisulfate (APS). After, completion of polymerization (8 h), the dark green colored dispersion of PANI nanoparticles is formed. This dispersion is treated with copious amount of 2-propanol for 2 h (to break the emulsion) and filtered using Buchner funnel. The wet cake is dispersed in chloroform and is subjected to homogenization for 30 min. The concentrated (˜50% solid content) dispersion of PANI nanorods is then stored for further use.

In next step, about 2 ml of above dispersion is diluted with 100 ml of chloroform to realize dilution ratio of 1:50. A square piece of foam (3.5″×3.5″) is dipped inside the above PANI nanorods/chloroform dispersion under stirring to initiate the infiltration, soaking and coating of PANI particles over foam's surface and pores. After 5 minutes, the coated foam substrate is removed from the dispersion, dried at 60° C. for 4 h and the loading of the PANI is found to be 0.009% by volume. The foam display mechanical flexibility, low density (0.0159 g/cm³) and high porosity (98.5%) along with surface resistivity of 10⁹ Ω/square, that makes it to qualify the antistatic criteria and suggest its utility for making low electrostatic charging (low contact electrification) electronic packaging/encasing material.

### Example 2

PANI nanorods decorated foam (˜0.031 volume % PANI) is prepared by wet mixing method as in example 1 by taking dilution ratio of 1:20. The coated foam display flexibility, low density and static charge dissipation capability as mentioned in Table 1. The qualification of static dissipative criteria suggests its use for making static charge dissipative (low triboelectric charging) electronic packaging/encasing material.

### Example 3

PANI nanorods decorated foam (˜0.055 volume % PANI) is prepared by wet mixing method as in example 1 by taking dilution ratio of 1:10. The coated foam display flexibility, low density and static charge dissipation capability as mentioned in Table 1.

### Example 4

PANI nanorods decorated foam (˜2.97 volume % PANI) is prepared by wet mixing method as in example 1 by taking 50 ml of above dispersion without any dilution. The coated foam display flexibility, low density and conducting nature with obvious static charge dissipation capability as mentioned in Table 1. The qualification of conductive criteria suggests its use for making static charge dissipative (low triboelectric charging) as well as electrostatic shielding electronic packaging/encasing material.

### Example 5

A control foam sample (blank foam or SP) without any PANI is prepared by successive treatment of foam with chloroform and water followed by oven drying at 60° C. for 4 h. The sample display properties mentioned in the Table 1.

### Example 6 to 8

### Preparation of Functionalized-Carbon Nanotubes Decorated Foam

### Example 6

Functionalized-carbon nanotubes (f-CNTs) decorated foam is prepared by wet chemical route using aqueous dispersion of f-CNTs (carboxyl functionalized CNTs) to impregnate foamed substrate followed by oven drying to eliminate water, leaving behind entangled network of f-CNTs over foam's surface. In a typical coating process, an aqueous (water based) dispersion of f-CNT (carboxyl functionalized CNTs prepared by HNO₃ treatment of CVD grown multiwall CNTs) with ˜0.002% (w/v) solid (f-CNT) content is prepared by high speed homogenization for 30 minutes followed by 30 minutes of ultrasonication. In next step, a square piece of foam (3.5″×3.5″) is dipped inside the above under stirring to achieve coating of f-CNTs over foam's surface as well as porous channels. After 5 minutes, the coated foam substrate is removed from the dispersion, dried at 60° C. for 4 h and the loading of the f-CNTs is found to be 0.004% by volume. As in case of PANI based foams, these f-CNTs decorated foams also display mechanical flexibility, low density (0.0159 g/cm³) and high porosity (98.5%) along with surface resistivity of 10¹⁰ Ω/square, that makes it to qualify the antistatic criteria and suggest its utility for making low electrostatic charging (low contact electrification) electronic packaging/encasing material. (Table 1).

### Example 7

An f-CNTs decorated foam sample (˜0.019 volume % f-CNTs) is prepared by water based wet mixing method in example 6 by treatment of foam with aqueous dispersion of f-CNT having ˜0.02% (w/v) solid content. The coated foam display flexibility, low density and static dissipative nature with properties as mentioned in Table 1.

### Example 8

An f-CNTs decorated foam sample (˜0.032 volume % f-CNTs) is prepared by water based wet mixing method in example 6 by treatment of foam with aqueous dispersion of f-CNT having ˜0.03% (w/v) solid content. The coated foam display flexibility, low density and static dissipative nature with properties as mentioned in Table 1.

### Example 9 to 13

### Preparation of Reduced Graphene Oxide Decorated Foam

### Example 9

Reduced graphene oxide (RGO) decorated foam is prepared by wet chemical route using water processable graphene precursor i.e. graphene oxide (GO) followed by chemical reduction to RGO. The GO is generated from exfoliation of graphitic oxide (via high speed shearing followed by ultrasonication) that was prepared by Hummers method (chemical oxidation route using graphite powder as carbon source and KMnO₄/NaNO₃ as oxidizing mixture). In a typical synthesis, known amount of graphite and NaNO₃ are added into 200 mL concentrated H₂SO₄ in an ice bath followed by the gradual addition of 9 gm of KMnO₄ (Graphite:KMnO₄:NaNO₃ ratio was 1:1:3), keeping the temperature below 30° C. due to exothermicity of the reaction. Afterward, the reaction mixture is placed under stirring at 25° C. for 18 h, forming a thick paste. Subsequently, the paste is gradually poured into 400 mL deionised water. After 20 min, another 1 L of deionised water is added to the mixture followed by the drop wise addition of 30 mL of 30% H₂O₂ solution to reduce the excess KMnO₄. The solution turns light brown after the addition of H₂O₂, it is then decanted and centrifuged followed by washing with deionised water till the pH is 7 and is dried at room temperature under vacuum for 24 h to obtain graphitic oxide solid.

In the next step aqueous dispersion of graphitic oxide with ˜0.02% (w/v) solid content is prepared by high speed homogenization of aqueous dispersion of precalculated amount of graphitic oxide powder for 30 minutes followed by 30 minutes of ultrasonication. In next step, a square piece of foam (3.5″×3.5″) is dipped inside the above GO/water dispersion under stirring to impregnate foamed substrate and achieve coating of GO over foam's surface as well as porous channels. After 5 minutes, the coated foam substrate is removed from the dispersion, dried at 50-60° C. for 4 h to eliminate water, leaving behind network of GO sheets over foam's. In the next step, GO coated foam is exposed to hydrazine vapours for 12 h to convert semiconducting GO into electrically conducting RGO with RGO loading of 0.003% by volume. These RGO decorated foams also display mechanical flexibility, the properties (Table 1) like low density (0.0160 g/cm³) and high porosity (98.5%) along with surface resistivity of 10¹⁰ Ω/square, enable it to qualify the antistatic criteria and suggest its utility for making low electrostatic charging (low contact electrification) electronic packaging/encasing material.

### Example 10

RGO decorated foam (˜0.016 volume % RGO) is prepared by water soluble precursor-reduction method as in example 9 by treatment of foam with aqueous dispersion of GO having ˜0.02% (w/v) solid content followed by reduction of coated GO to RGO. The coated foam display flexibility, low density and static dissipative nature with properties as mentioned in Table 1.

TABLE 1
Filler content, density, porosity, surface resistivity and electrostatic
compliance of the different nanofillers coated packaging foams

| | | | | | Electrostatic com- |
|---|---|---|---|---|---|
| | | | Po- | Surface | pliance (Insulating, |
| | Filler and | Den- | ros- | resis- | Antistatic, Static |
| S. | loading level | sity | ity | tivity | Dissipative or Con- |
| No. | (volume %) | (g/cm³) | (%) | (Ω/square) | ductive) |
| 1. | Pure Sponge | 0.0158 | 98.5 | 10¹² | Insulating |
| | (SP) | | | | |
| 2. | RGO (0.003) | 0.0160 | 98.5 | 10¹⁰ | Antistatic |
| 3. | RGO (0.016) | 0.0167 | 98.4 | 10⁸ | Static dissipative |
| 4. | RGO (0.024) | 0.0171 | 98.3 | 10⁷ | Static dissipative |
| 5. | RGO (0.058) | 0.0189 | 98.2 | 10⁵ | Static dissipative |
| 6. | RGO (0.254) | 0.0295 | 97.2 | 10⁴ | Conductive |
| 7. | fCNT (0.004) | 0.0159 | 98.5 | 10¹⁰ | Antistatic |
| 8. | fCNT (0.019) | 0.0163 | 98.4 | 10⁹ | Antistatic |
| 9. | fCNT (0.032) | 0.0165 | 98.4 | 10⁷ | Static dissipative |
| 10. | PANI (0.009) | 0.0159 | 98.5 | 10⁹ | Antistatic |
| 11. | PANI (0.031) | 0.0162 | 98.4 | 10⁷ | Static dissipative |
| 12. | PANI (0.055) | 0.0165 | 98.4 | 10⁵ | Static dissipative |
| 13. | PANI (2.97) | 0.0515 | 95.1 | 10⁴ | Conductive |

### Example 11

RGO decorated foam (˜0.024 volume % RGO) is prepared by water soluble precursor-reduction method as in example 9 by treatment of foam with aqueous dispersion of GO having ˜0.03% (w/v) solid content followed by reduction of coated GO to RGO. The coated foam display flexibility, low density and static dissipative nature with properties as mentioned in Table 1.

### Example 12

RGO decorated foam (˜0.058 volume % RGO) is prepared by water soluble precursor-reduction method as in example 9 by treatment of foam with aqueous dispersion of GO having ˜0.05% (w/v) solid content followed by reduction of coated GO to RGO. The coated foam display flexibility, low density and conducting nature with properties as mentioned in Table 1.

### Example 13

RGO decorated foam (˜0.254 volume % RGO) is prepared by water soluble precursor-reduction method as in example 9 by treatment of foam with aqueous dispersion of GO having ˜0.3% (w/v) solid content followed by reduction of coated GO to RGO. The coated foam display flexibility, low density and static dissipative nature with properties as mentioned in Table 1.

### Advantages of the Invention

The main advantages of the present invention are:
1. It gives a facile and scalable approach for making antistatic and electrostatic dissipative foams via which a variety of electrically conducting nanofillers (e.g. conducting polymers, carbon nanotubes, graphene etc.) can be easily decorated over the insulating surface of foamed/porous substrate.
2. The decoration actualizes onset of surface conduction without disturbing physical and mechanical properties of foamed substrate.
3. The electrically conducting nanofillers (0.003 to 2.97 volume %) can be easily decorated over foamed substrate by carefully controlling the concentration/nature of magnetic nanoparticles in dispersing medium which in turn can provide the surface conduction to the otherwise electrically insulating substrate.
4. These nanofiller based decorations are corrosion resistant and tend to provide stable operation (long service life) compared to metal based coatings that are susceptible to corrosion and consequent loss of antistatic/static-dissipative performance.
5. The combination of low density, mechanical flexibility, resilience and surface conductivity collectively contribute towards their excellent shock absorption and static charge dissipation capabilities.
6. These foams display surface resistivity value <10⁹ ohm/sq along with static charge dissipation time <0.5 sec, which clearly demonstrate their potential for static charge dissipative materials for electronic packaging applications.
7. The process can also extended to other substrates like fabrics (e.g. cotton, nylon or polyester cloth), wood, paper and other porous materials.
8. These foams could also be useful for antistatic dust filters, clean-room/medical apparels, static-free footwear, static dissipative upholstery items, antistatic/dissipative floorings/tiles etc.
9. The process is simple, economically feasible, environmentally benign as well as scalable and involves only few processing steps.

We claim:

1. Electrically conducting nanofillers (ECNFs) decorated conducting foams comprising decoration of 0.003 to 2.97 volume % of ECNFs over otherwise electrically insulating surface of foam providing them electrical conductivity without disturbing foamed morphology, physical or mechanical properties.

2. The foams as claimed in claim 1, wherein electrically conducting nanofillers (ECNFs) used are selected from the group consisting of activated carbon, exfoliated graphite, carbon based filler or doped conducting polymers wherein the dopant is selected from a group comprising of para toluene sulfonic acid (PTSA), cardanol azophenyl sulfonic acid (CDSA) and dodecyl benzene sulfonic acid (DBSA), camphor sulfonic acid (CSA), Lignin sulfonic acid (LSA) preferably DBSA.

3. The foams as claimed in claim 2, wherein conducting polymer is selected from the group consisting of polyaniline, polypyrrole or polythiophenes preferably polyaniline.

4. The foams as claimed in claim 2, wherein the carbon based filler is selected from a group comprising of graphene, graphene oxide (GO), functionalized carbon nanotubes (f-CNTs) or activated carbon fibers.

5. The foams as claimed in claim 1, wherein said foam exhibit density in the range of 0.0159 to 0.0515 g/cm³, porosity is in the range of 95.1 to 98.5%, surface resistivity is in the range of 10¹¹ to 10⁴ ohms/square and static charge decay time of <2.0 seconds.

6. The foams as claimed in claim 1, wherein said foam is useful for electronic packaging applications, antistatic dust filters, clean-room/medical apparels, footwear and static dissipative upholstery items and also display mechanical flexibility (can be bent, rolled or wrapped), resilience (shock absorbing ability), good corrosion resistance, sound/vibration damping characteristics and static charge dissipation capabilities to act as an ideal candidate for electronic packaging applications.

7. A process for the preparation of ECNFs decorated conducting foams as claimed in claim 1 and the said process comprising the steps of:
(i) addition of ECNFs in dispersion medium to obtain a 0.001-0.5% (w/v) dispersion;
(ii) dipping of the porous substrate inside the dispersion as obtained in step (i) for period in the range of 1 to 5 minutes under agitation to obtain wet impregnated foam;
(iii) drying the wet impregnated foam as obtained in step (ii) at temperature in the range of 40 to 80° C. for period in the range of 4 to 8 h to obtain the ECNFs decorated conducting foams.

8. A process as claimed in step (i) of claim 7, wherein the dispersing medium is selected from a group comprising of toluene, benzene, acetone, chloroform, kerosene, distilled water, ethanol, propanol, methanol, dimethylsulfoxide (DMSO), dimethylformamide (DMF), N-methyl pyrrolidone (NMP), either alone or combination thereof.

9. A process as claimed in step (i) of claim 4, wherein the dispersion medium is preferably chloroform for PANI nanorods and preferably distilled water for both f-CNTs and GO.

10. A process as claimed in step (ii) of claim 7, wherein the porous substrate is selected from the group consisting of polyurethane (PU) foam, fabrics, wood and paper and other porous materials preferably PU foam.
